(19) United States
(12) Patent Application Publication
(10) Pub. No.: US 2021/0288746 A1
(43) Pub. Date: Sep. 16, 2021

(54) Error Correction for LDPC Decoders

(71) Applicant: Tesat-Spacecom GmbH & Co. KG, Backnang (DE)

(72) Inventor: Franz Josef Hagmanns, Backnang (DE)

(73) Assignee: Tesat-Spacecom GmbH & Co. KG, Backnang (DE)

(21) Appl. No.: 17/197,217

(22) Filed: Mar. 10, 2021

(30) Foreign Application Priority Data
Mar. 10, 2020 (DE) 10 2020 106 501.9

(51) Int. Cl. H04L 1/00; H03M 13/11

(52) U.S. Cl. CPC H04L 1/005; H03M 13/1131

(57) ABSTRACT

A reception unit for use in a data link and a method for error correction on a reception word in a data link are specified. A low-density parity-check code, LDPC code, is used to iteratively adapt the reception word by virtue of bit node messages and check node messages being exchanged. The check node messages that are transmitted to the bit nodes are quantized in three levels and adopt the values −1, 0 or +1. The method may thus be implemented with low computational expenditure.

### FIELD OF THE INVENTION

The present description relates in general to the technical field of data transmission and error detection and error correction in transmitted data at a receiver. The description relates in particular to a reception unit for use in a data link and to a method for error correction on a reception word.

### BACKGROUND

What are known as low-density parity-check codes, LDPC codes, are linear block codes for error correction purposes. LDPC codes describe a plurality of continuous parity checks with the aid of a matrix.

The basic principles of LDPC codes may be found in Robert G. Gallager: Low-Density Parity-Check Codes. M.I.T. Press Classic Series, Cambridge Mass., USA, 1963.

LDPC decoders generally use finely quantized input values, for example from an A/D converter with a resolution of 4 to 6 bits, and are well-suited to error correction, but require a high computing power.

### BRIEF SUMMARY

An aspect may relate to specifying an LDPC decoder having reduced complexity and reduced requirement in terms of computing power.

According to a first aspect, a reception unit for use in a data link is specified. The reception unit has a preprocessing unit and a decoder. The preprocessing unit is designed to quantize an analogue value, received from a transmission channel, into a three-level signal Q, wherein the three-level signal may adopt a first value, a second value or a third value, wherein the first value corresponds to a first logic state, the third value corresponds to a second logic state and the second value corresponds to an indeterminate logic state. The decoder comprises a multiplicity of bit nodes and a multiplicity of check nodes, wherein a number of bit nodes is linked in each case to one check node. The decoder is designed to iteratively update bit node messages in accordance with the rule:

$${B}^{( n )} ( k ) = r ( k ) + {\sum }_{l ∈ γ ( k )} {C}_{k}^{( n - 1 )} ( l ) ,$$

The following holds true here:

B⁽ⁿ⁾(k) is the nth iteration of a message from the bit node n to the check node linked to the bit node n.

Cₖ⁽ⁿ⁾ is the nth iteration of a message from the check node n to the bit node k; and

γ(k) is a set of indices of the check nodes linked to the bit node k.

The decoder is designed to iteratively update check node messages to the bit nodes in accordance with the rule:

$${C}_{l}^{( n )} ( k ) = {\prod }_{λ ∈ β ( k ) , λ \neq l} Q ( {B}^{( n )} ( λ ) - {C}_{λ}^{( n - 1 )} ( k ) ) ,$$

The following holds true here:

β(k) is a set of indices of the bit nodes linked to the check node k;

The decoder is designed to determine the three-level signal Q(x) as follows:

$$Q ( x ) = \{ \begin{matrix}+ 1 , & x > 0 , \\ 0 , & x = 0 , \\ - 1 , & x < 0\end{matrix} .$$

Information is transmitted via the transmission channel, for example in the form of analogue voltage levels. The voltage level is recorded on the receiver side and a value is assigned to this voltage level. The transmission channel is combined with the preprocessing unit in functional terms by the link to form what is known as an erasure channel. An erasure channel denotes a channel in information theory that receives an information bit (generally having two states, logic 0 or logic 1) at its input and outputs an information bit (generally having two states, logic 0 or logic 1) or a transmission error E at its output. The erasure channel thus has three possible output values.

The three-level signal Q may adopt three values. A first value may correspond to a logic 0, and a third value may correspond to a logic 1. This thus represents the two values that form a single information bit. The second value is used when it is not possible to assign the received analogue value unambiguously to the first or third value.

The preprocessing unit and the decoder may be accommodated in structural terms in a common structural unit. They may however also be spatially and structurally separate from one another. The preprocessing unit may for example be connected directly to an output of a link and transfer the quantized three-level signal to the decoder as channel output. The preprocessing unit delivers the signal Q to the decoder, regardless of the structural arrangement and assignment.

There is provision for the messages from the check nodes to the bit nodes likewise to be quantized in three levels. This has the advantage that the processing of the check node messages that are transmitted to the bit nodes is able to be performed very quickly using digitally operating modules, because it is possible to use simple operations. This results from the fact that the signal Q quantized in three levels uses the values +1 (for example logic 1), 0 (indeterminate logic state) and −1 (for example logic 0). The check node message is ascertained as the product of a plurality of such values quantized in three levels. If a multiplication by a plurality of factors contains a factor having the value 0, then the result of the multiplication is likewise 0. This indicates that the result of the multiplication is impacted by uncertainty, which happens whenever the value of an individual factor is impacted by uncertainty. The multiplication by −1 merely changes the mathematical sign.

Conventional decoders that operate using bit nodes and check nodes use a finer quantization for the check node messages, sometimes having considerably more than three quantization levels. By way of example, a resolution depth of 32 levels for the positive value and 32 levels for the negative value (corresponding to 6 bits) may be used for this purpose. The check node message then however has to be ascertained with a great deal of complexity and consumption of computing power. In contrast thereto, a three-level quantization is used in this case, which allows rapid generation of the check node message, because it is possible to work with operations that are able to be performed in a very short time in digitally operating systems (that for example use the binary system).

According to one embodiment, the decoder is a low-density parity-check code, LDPC code.

A low-density parity-check code, LDPC code, is a linear block code for error correction purposes and describes a plurality of continuous parity checks with the aid of a matrix, said parity checks being applied to a reception sequence.

In the case of an LDPC code, a plurality of subsets of bit nodes are selected from a multiplicity of bit nodes and grouped together to form groups in an alternating structure. Such a group is linked to a check node. Thus, by way of example, in each case four bit nodes in an alternating structure may be linked to a check node. A check node then determines a check value for the messages (the logic state of a bit node) that it receives from the bit nodes linked thereto.

By way of example, the check value may be determined by linking together the messages from one group of bit nodes with a predefined mathematical or logical operation. Such a mathematical or logical operation is conventionally the modulo-2 addition. The check value is then used to ascertain a check node message for the bit nodes, as described further below.

At the beginning, the bit nodes are initialized with the values of the received bits of the reception word r(k). These may adopt said three values: −1, 0 or +1. Each check node then ascertains a check value based on the values that the check node receives from those bit nodes that are linked to the current check node.

In the case of an LDPC code, error-free transmission is typically assumed when the check value in a check node has the value 0. In the case of a transmission error, the check value in a check node becomes 1:

B(0)·B(1)·B(2)·B(3)=1.

This equation proves that the bit nodes 0 to 3 in a group are combined, and their values are used to calculate the check value in a check node. In the present case, the check value has the value 1.

Based on the check value and a subset (all bit nodes apart from one) of the bit nodes linked to the check node, it is then possible to ascertain what the value of the remaining bit node would have to be so that the check value 0 (which is the result in the error-free case) is established in the current check node. The following equation expresses what value the bit node 0 has to have so that the correct check value for the error-free case results at the check node 0:

C₀(0)=B(1)·B(2)·B(3),

The equation that then follows likewise expresses what value the bit node 1 has to have so that the correct check value for the error-free case results at the check node 0:

C₁(0)=B(0)·B(2)·B(3),

Each check node calculates such a target value for each bit node that is linked thereto by using all other bit nodes linked to the check node for this purpose. Each bit node is linked to a plurality of check nodes and receives information from each check node as to what its value would have to be so that the check value calculation indicates error-free transmission in the individual check node. Each bit node may then use this information from all of the check nodes linked thereto and the value received via the transmission channel to draw conclusions, for example through a majority decision, as to what its value would have to be so that the value in the fewest check nodes indicates a transmission error. This is performed for all bit nodes, and in a next step the bit nodes receive a new value and the method is performed again with the new values of the bit nodes until the values of the bit nodes approach a conflict-free reception word (=reception sequence, amount of all bits at all bit nodes) in which all check nodes report error-free transmission with correct check values.

According to a further embodiment, the preprocessing unit has a first comparator and a second comparator, wherein the first comparator is designed to check whether the received analogue value is above a first threshold value, wherein the second comparator is designed to check whether the received analogue value is below a second threshold value, and wherein the preprocessing unit is designed to output the first value of the three-level signal when the received analogue value is above the first threshold value, to output the third value of the three-level signal when the received analogue value is below the second threshold value, and otherwise to output the second value of the three-level signal.

This describes how the initial values of the bit nodes are set based on a reception sequence. Based on these initial values, the following iterative steps are then performed in order to approach the error-free reception sequence (this is the reception sequence in which the bit node values do not lead to any incorrect check values in the check nodes).

According to a further embodiment, the preprocessing unit is designed, for each reception sequence containing multiple information bits, in each case to ascertain one value per information bit according to the three-level signal Q and in each case to transmit a value to each bit node of the decoder.

This describes how a reception sequence or a word consisting of multiple bits is distributed to the bit nodes. A word that is received by the reception unit consists of multiple information bits, the number of which corresponds to the number of bit nodes in the decoder.

According to a further embodiment, all of the check nodes are linked to the same number of bit nodes in an alternating grouping of the bit nodes.

By way of example, each check node is linked to four bit nodes. In this case, no check node is linked to the same four bit nodes, that is to say the check nodes are linked to groups of bit nodes that are structured differently or alternately. This allows a bit node to receive messages from different check nodes in conjunction with other bit node values, in order thereby to increase the probability of error detection and error correction.

According to a further aspect, a data link is specified. The data link has: a coder, a modulator linked to the coder, a transmission channel linked to the modulator, and a reception unit as described herein. The reception unit is linked to the transmission channel such that data are able to be transmitted from the coder to the reception unit.

The data link links a data source to a data consumer and is designed in particular as a binary erasure channel. Using the reception unit and the decoder designed in the manner described herein, error correction is able to be performed with low computational expenditure and in a short time.

According to one embodiment, the modulator is designed to perform binary phase shift keying and to output a signal thereby generated on the transmission channel.

When the modulator operates in accordance with the binary phase shift keying principle, there are two different values on the transmission channel. This is thus a binary channel. A multiplicity of values transmitted in succession are read on the receiver side as reception word and fed to the error checking and correction described above.

According to a further aspect, a method for error correction on a response word on a data link is specified. The method has the following steps:

quantizing an analogue value into a three-level signal Q, wherein the three-level signal may adopt a first value, a second value or a third value, wherein the first value corresponds to a first logic state, the third value corresponds to a second logic state and the second value corresponds to an indeterminate logic state;

assigning a multiplicity of quantized analogue values to a multiplicity of bit nodes;

determining check values in a multiplicity of check nodes, wherein each check node is linked to a predefined group of bit nodes;

iteratively updating bit node messages to the check nodes in accordance with the rule:

$${B}^{( n )} ( k ) = r ( k ) + {\sum }_{l ∈ γ ( k )} {C}_{k}^{( n - 1 )} ( l ) ,$$

wherein:

B⁽ⁿ⁾(k) is the nth iteration of a message from the bit node n to the check node linked to the bit node n;

Cₖ⁽ⁿ⁾ is the nth iteration of a message from the check node n to the bit node k; and

γ(k) is a set of indices of the check nodes linked to the bit node k;

iteratively updating check node messages to the bit nodes in accordance with the rule:

$${C}_{l}^{( n )} ( k ) = {\prod }_{λ ∈ β ( k ) , λ \neq 1} Q ( {B}^{( n )} ( λ ) - {C}_{λ}^{( n - 1 )} ( k ) ) ,$$

wherein β(k) is a set of indices of the bit nodes linked to the check node k; and

wherein the three-level signal Q(x) is determined as follows:

$$Q ( x ) = \{ \begin{matrix}+ 1 , & x > 0 , \\ 0 , & x = 0 , \\ - 1 , & x < 0\end{matrix} .$$

The steps of the method correspond essentially to the functions of the reception unit and in particular of the decoder. The detailed description and explanation as were given with regard to the reception unit therefore apply to the method. A repetition is dispensed with at this point.

The method may be implemented for example as a command sequence on a processor or controller. In this case, the processor or controller is the reception unit or part thereof, for example the decoder. It is also conceivable for a programmable logic gate (such as for example an FPGA, field-programmable gate array) to be configured such that it performs the method, which may advantageously increase the performance speed. Other processors or controllers may be used, such as for example an ASIC (application-specific integrated circuit).

### BRIEF DESCRIPTION OF THE DRAWINGS

Exemplary embodiments are described in more detail below with reference to the appended drawings. The illustrations are schematic and not to scale. Identical reference signs refer to identical or similar elements. In the figures:

FIG. 1 shows a schematic illustration of a Tanner graph, the principles of which define the operating basis of an LDPC code.

FIG. 2 shows a schematic illustration of a data link.

FIG. 3 shows a schematic illustration of a reception unit.

FIG. 4 shows a schematic illustration of a preprocessing unit.

### DETAILED DESCRIPTION OF EXEMPLARY EMBODIMENTS

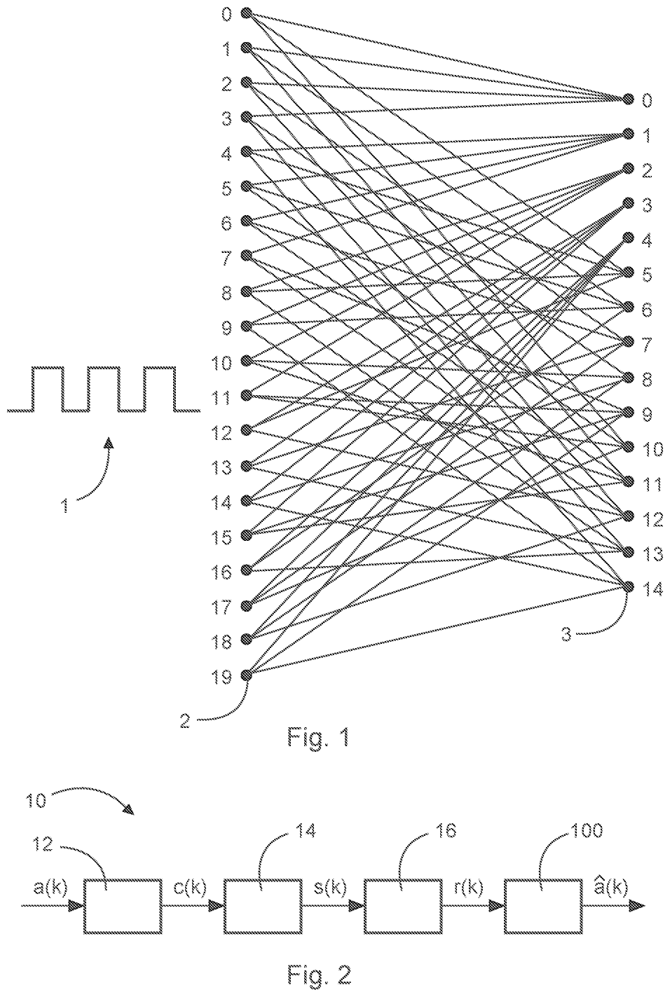

FIG. 1 shows a schematic illustration of a Tanner graph, in order to explain the basic operation of an LDPC code and the operation of the reception unit, including decoder, set forth here.

A reception sequence 1, in this case a binary reception sequence, is transmitted to the bit nodes 2. The number of bits in the reception sequence, which corresponds to the number of bit nodes, is referred to as reception word. In the present case, the Tanner graph contains 20 bit nodes (0 . . . 19), such that a reception word consists of 20 bits. The Tanner graph also contains 15 check nodes (0 . . . 14).

Four bit nodes are linked in each case to a check node. By way of example, the bit nodes 0 . . . 3 are linked to the check node 0, the bit nodes 4 . . . 7 are linked to the check node 1, etc. There are also groupings of bit nodes other than groups containing successive bit nodes. By way of example, the bit nodes 0, 4, 8, 12 are linked to the check node 5. In any case, each check node is linked to a combination of bit nodes that is present exactly once.

In order to indicate error-free transmission, for each reception word to the bit nodes, it is necessary to meet the condition whereby each check node meets the parity or check condition. This check condition makes provision for the check value to have the value 0. The check value is normally calculated as follows (given here by way of example for the check node 0, the same operation being performed for all check nodes):

c(0)⊕c(1)⊕c(2)⊕c(3)=0,

wherein ⊕ means a modulo-2 addition. If c(k) is replaced with BPSK-modulated keys (binary phase shift keying, BPSK), the parity condition for the check node 0 may be expressed as follows:

s(0)·s(1)·s(2)·s(3)=1,

The decoding is an iterative process. The values of the bit nodes are first of all set to the bits of the received reception word, and the check value is calculated in the check nodes, shown here again by way of example for the check node 0:

B(0)·B(1)·B(2)·B(3)=1.

From the bit node values present at the check node 0, it is then possible to perform reverse calculation and determine a required value for a bit node by applying the other bit node values of this check node. It is then possible to calculate the required value for the bit node 0 in the check node 0 by applying the values of the other bit nodes from this group, that is to say the bit nodes 1 to 3:

C₀(0)=B(1)·B(2)·B(3),

The same thing happens for the reverse-calculated value for the other three bit nodes 1 to 3, shown by way of example for the bit node 1:

C₁(0)=B(0)·B(2)·B(3),

The values of the bit nodes 0, 2 and 3 are thus used here to determine the value of the bit node 1 such that the check value is correct.

As may be seen in FIG. 1, the bit node 0 is linked to the check nodes 0, 5, 10. A required value of the bit node 0 is calculated in each of these three check nodes (based on the in each case remaining bit nodes in the respective groups). Using these calculated values and the originally received bit at the bit node 0, it is then possible to iteratively ascertain a value for the bit node 0 with regard to what this value would have to be in order for the parity conditions to be met at all check nodes. The value of the bit node is then changed and the method is run through again.

In conventional LDPC decoders, highly resolved values are used to determine the values of the bit nodes, for example between 4 and 6 bits. In order to reverse-calculate the assumed values of the bit nodes based on the values of the check nodes, use is made of probability theory techniques.

In contrast thereto, it is proposed here for the values of the bits of the reception word and the values of the check nodes to be quantized and to adopt exclusively one of the values −1, 0 and +1.

In a first step, the values of the reception word that are quantized in this way are assigned to the bit nodes, and the bit nodes are initialized with these values. The initial values are given here as r(k), wherein k indicates the number of the bit node. The check values are then calculated in the check nodes and a reverse calculation is performed in each node for each connected bit node as to what the value of the bit node in question has to be in order for the parity condition to be met (see above).

The bit nodes receive feedback from multiple check nodes and thus change their value for the next iteration step when required, for example according to a majority decision regarding the reverse-calculated values received from the check nodes and taking into consideration the initial value from the reception word. In the nth iteration step, the (new) value of a bit node (here for example the bit node 0) is set to the sum that corresponds to the value of the associated bit from the reception word (r(0)) and the responses from the check nodes (C, here the responses from the check nodes 0, 5 and 10 for the bit node 0 from the previous iteration step n-1):

B⁽ⁿ⁾(0)=r(0)+C₀⁽ⁿ⁻¹⁾(0)+C₀⁽ⁿ⁻¹⁾(5)+C₀⁽ⁿ⁻¹⁾(10).

Using the following quantization function, wherein x is an arbitrary integer,

$$Q ( x ) = \{ \begin{matrix}+ 1 , & x > 0 , \\ 0 , & x = 0 , \\ - 1 , & x < 0\end{matrix} .$$

it is possible to state the following for the calculation of the response at a bit node by a check node:

C₀⁽ⁿ⁾(0)=Q(\hat{B}⁽ⁿ⁾(1))·Q(\hat{B}⁽ⁿ⁾(2))·Q(\hat{B}⁽ⁿ⁾(3)),

The response from the check node 0 to the bit node 0 for the value of the bit node 0 in the iteration step n corresponds to the product of the quantized values of the bit nodes 1, 2 and 3, wherein the following holds true:

\hat{B}⁽ⁿ⁾(k)=B⁽ⁿ⁾(k)−Cₖ⁽ⁿ⁻¹⁾(0).

This means that, in order to update the value of a check node, use should be made only of bit node information that was received by the used bit node exclusively from other check nodes in the previous iteration step. This is achieved by again subtracting the information that the check node to be updated transmitted to the bit node to be used for the update in the previous iteration step.

FIG. 2 shows a schematic illustration of a data link 10. The data link contains a coder 12 that codes values and outputs them to a modulator 14. The moderator outputs a modulated bit sequence on the transmission channel 16. At the output of the transmission channel 16, a reception sequence is output to the reception unit 100.

The reception unit 100 performs the method described above. The reception unit may be linked to a data consumer (not shown) and forwards the received data to the data consumer.

The data link 10 may be used for any data transmission link between a data source and a data consumer. The transmission channel may contain a wireless or wired transmission section.

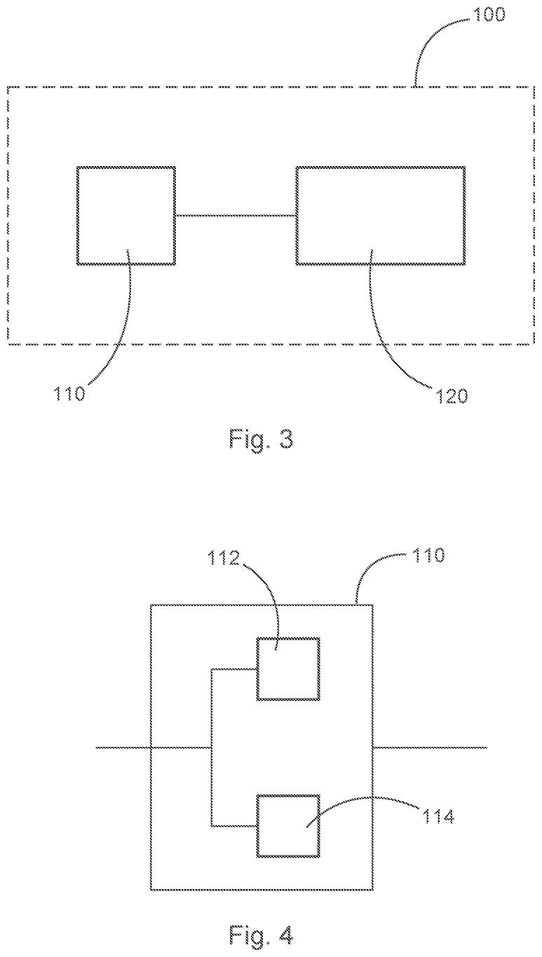

The transmission channel 16 may be what is known as an erasure channel and already output three values (logic 1, logic 0, indeterminate) at its output. This distinction between the three values may however also be made by a dedicated unit that is present separately, for example by the preprocessing unit (see FIG. 3).

FIG. 3 shows a schematic illustration of a reception unit 100. The reception unit 100 has a preprocessing unit 110 and a decoder 120. The preprocessing unit 110 may be spatially and structurally separate from the decoder. By way of example, the preprocessing unit 110 may be arranged as a functional component of the transmission channel 16 (see FIG. 2). In any case, a bit that may adopt three values: logic 0, logic 1, indeterminate, is delivered to the decoder 120. This is the functional prerequisite for the decoder, and it is irrelevant whether this input value arrives at the decoder directly from the transmission channel or from a separate functional unit.

FIG. 4 shows an exemplary structure of the preprocessing unit 110 in order to obtain the three output values logic 0, logic 1 and indeterminate.

The preprocessing unit 110 has two comparators 112, 114. An information bit is conveyed to the two comparators. If a voltage level of the information bit is greater than a first threshold value, then the first comparator 112 outputs a value such that the preprocessing unit outputs a first logic value, for example a logic 1. If the voltage level of the information bit is on the other hand lower than a second threshold value, then the second comparator 114 outputs a value such that the preprocessing unit outputs a second logic value, for example a logic 0. If the value of the voltage level is between the first and second voltage level (in each case including this bound), then the preprocessing unit 110 outputs “indeterminate” as output value.

The preprocessing unit 110 may thus be used to provide the bit nodes initially with the associated three-level values of the reception word.

It is additionally pointed out that “comprising” or “having” does not rule out any other elements or steps, and “a” or “an” does not rule out a multiplicity. It is furthermore pointed out that features or steps that have been described with reference to one of the exemplary embodiments above may also be used in combination with other features or steps of other exemplary embodiments described above. Reference signs in the claims should not be considered to be restrictive.

### LIST OF REFERENCE SIGNS

1 Reception sequence
2 Bit nodes
3 Check nodes
10 Data link
12 Coder
14 Modulator
16 Transmission channel
100 Reception unit
110 Preprocessing unit
112 First comparator
114 Second comparator
120 Decoder, LDPC decoder

1. A reception unit for use in a data link, comprising:
a preprocessing unit configured to quantize an analogue value, received from a transmission channel, into a three-level signal Q, wherein the three-level signal may adopt a first value, a second value or a third value, wherein the first value corresponds to a first logic state, the third value corresponds to a second logic state and the second value corresponds to an indeterminate logic state; and
a decoder having a multiplicity of bit nodes and a multiplicity of check nodes, wherein a number of bit nodes is linked in each case to one check node;
wherein the decoder is configured to iteratively update bit node messages in accordance with the rule:
$${B}^{( n )} ( k ) = r ( k ) + {\sum }_{l ∈ γ ( k )} {C}_{k}^{( n - 1 )} ( l ) ,$$
wherein:
B⁽ⁿ⁾(k) is the nth iteration of a message from the bit node n to the check node linked to the bit node n;
Cₖ⁽ⁿ⁾ is the nth iteration of a message from the check node n to the bit node k; and
γ(k) is a set of indices of the check nodes linked to the bit node k;
wherein the decoder (120) is configured to iteratively update check node messages to the bit nodes in accordance with the rule:
$${C}_{l}^{( n )} ( k ) = {\prod }_{λ ∈ β ( k ) , λ \neq 1} Q ( {B}^{( n )} ( λ ) - {C}_{λ}^{( n - 1 )} ( k ) ) ,$$
wherein β(k) is a set of indices of the bit nodes linked to the check node k; and
wherein the decoder is configured to determine the three-level signal Q(x) as follows:
$$Q ( x ) = \{ \begin{matrix}+ 1 , & x > 0 , \\ 0 , & x = 0 , \\ - 1 , & x < 0\end{matrix} .$$

2. The reception unit according to claim 1,
wherein the decoder is a low-density parity-check code.

3. The reception unit according to claim 1,
wherein the preprocessing unit comprises a first comparator and a second comparator;
wherein the first comparator is configured to check whether the received analogue value is above a first threshold value;
wherein the second comparator is configured to check whether the received analogue value is below a second threshold value;
wherein the preprocessing unit is configured to output the first value of the three-level signal when the received analogue value is above the first threshold value, to output the third value of the three-level signal when the received analogue value is below the second threshold value, and otherwise to output the second value of the three-level signal.

4. The reception unit according to claim 1,
wherein the preprocessing unit is configured, for a reception sequence containing multiple information bits, in each case to ascertain one value per information bit according to the three-level signal Q and in each case to transmit a value to each bit node of the decoder.

5. The reception unit according to claim 1,
wherein all of the check nodes are linked to the same number of bit nodes in an alternating grouping of the bit nodes.

6. A data link, comprising:
a coder;
a modulator linked to the coder;
a transmission channel linked to the modulator;
a reception unit according to claim 1;
wherein the reception unit is linked to the transmission channel such that data are able to be transmitted from the coder to the reception unit.

7. The data link according to claim 6,
wherein the modulator is configured to perform binary phase shift keying and to output a signal thereby generated on the transmission channel.

8. A method for error correction on a response word on a data link, comprising:
quantizing an analogue value into a three-level signal Q, wherein the three-level signal may adopt a first value, a second value or a third value, wherein the first value corresponds to a first logic state, the third value corresponds to a second logic state and the second value corresponds to an indeterminate logic state;
assigning a multiplicity of quantized analogue values to a multiplicity of bit nodes;
determining check values in a multiplicity of check nodes, wherein each check node is linked to a predefined group of bit nodes;
iteratively updating bit node messages to the check nodes in accordance with the rule:
$${B}^{( n )} ( k ) = r ( k ) + {\sum }_{l ∈ γ ( k )} {C}_{k}^{( n - 1 )} ( l ) ,$$
wherein:
B⁽ⁿ⁾(k) is the nth iteration of a message from the bit node n to the check node linked to the bit node n;
Cₖ⁽ⁿ⁾ is the nth iteration of a message from the check node n to the bit node k; and
γ(k) is a set of indices of the check nodes linked to the bit node k;
iteratively updating check node messages to the bit nodes in accordance with the rule:
$${C}_{l}^{( n )} ( k ) = {\prod }_{λ ∈ β ( k ) , λ \neq 1} Q ( {B}^{( n )} ( λ ) - {C}_{λ}^{( n - 1 )} ( k ) ) ,$$
wherein β(k) is a set of indices of the bit nodes linked to the check node k; and
wherein the three-level signal Q(x) is determined as follows:
$$Q ( x ) = \{ \begin{matrix}+ 1 , & x > 0 , \\ 0 , & x = 0 , \\ - 1 , & x < 0\end{matrix} .$$
